(19) United States
(12) Patent Application Publication
(10) Pub. No.: US 2007/0226563 A1
(43) Pub. Date: Sep. 27, 2007

(54) Test Method and Test Device for Testing an Integrated Circuit

(76) Inventors: Reinhard Buchner, Rottenburg (DE); Christian Ebner, Deggendorf (DE); Stefan Mosel, Regensburg (DE); Peter Rauscher, Kirchroth (DE); Arndt Voigtlander, Lappersdorf (DE)

Correspondence Address: LERNER GREENBERG STEMER LLP, P O BOX 2480, HOLLYWOOD, FL, 33022-2480, US

(21) Appl. No.: 11/597,139

(22) PCT Filed: May 24, 2005
(86) PCT No.: PCT/EP05/52365

§ 371 Date: Nov. 20, 2006

(30) Foreign Application Priority Data
Jun. 8, 2004 (DE) 10 2004 027 860.1

(51) Int. Cl. G01R 31/317

(52) U.S. Cl. 714/727

(57) ABSTRACT

A test method and a test device for testing an integrated circuit are configured to allow for a test device which dispenses with the hardware provision of the boundary scan cells in the device. For this purpose, the boundary scan cells are reproduced by way of a boundary scan program. All functionalities of the chain of boundary scan cells and the TAP interface are fulfilled by the use of the boundary scan program, which is executed by a program-controlled control device that is controlled by the integrated circuit.

The invention relates to a test method and a test device for testing an integrated circuit.

The technical field of the invention relates to the boundary scan testing of integrated circuits. Boundary scan testing is a generally known method for testing complicated digital circuits. Boundary scan testing implements an electrical test method for detecting manufacture-related connection errors (short circuits due to soldering jumpers or line breaks). The ANSI/IEEE standard 1149.1 was developed to provide a commercial standard for boundary scan testing. The standard is widely accepted by manufacturers of integrated circuits.

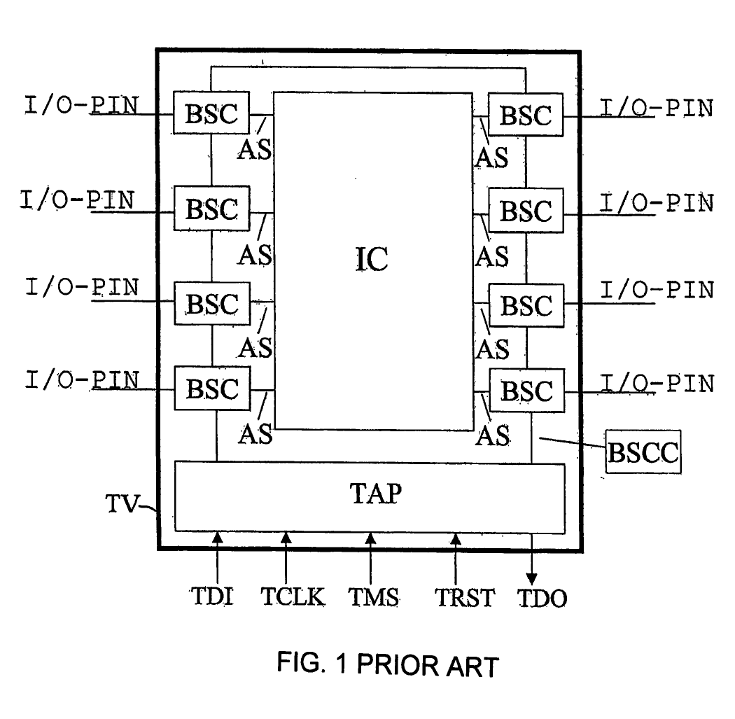

The schematic block circuit diagram in FIG. 1 shows a generally known test device for boundary scan testing on an integrated circuit. The test for connection errors is implemented by creating virtual test points in a test device TV designed according to the IEEE 1149.1 standard. Every external terminal I/o-PIN of the integrated circuit IC is provided internally with a simple additional circuit, referred to as a boundary scan cell BSC. All the boundary scan cells BSC are linked in a serial manner to a chain BSCC (Boundary Scan Cell Chain), which comprises the entire external terminal structure I/O-PIN of the test device TV.

Implementation of a boundary scan method assumes that the test device TV has four specifically reserved control and data pins. These are the test data input TDI and the test data output TDO, a test clock TCLK, which can typically be up to 15 MHz, and a test mode select terminal TMS. There can optionally be a fifth pin in the form of a test logic reset TRST, which the scan control logic or chain BSCC of the boundary scan cells BSC uses to switch to a defined mode. These pins, together with the scan logic that is a function of the respective wiring of the integrated circuit IC, form the test access port TAP.

Space is disadvantageously required for the boundary scan cells BSC within the test device TV. A large space requirement is associated with high costs in the case of integrated circuits, such that there is always a tendency to reduce the space requirement. Reducing the space requirement of the test device TV also reduces the costs of the test device TV. It is then possible to test integrated circuits more economically.

The object of the present invention is therefore to cut down on space for testing an integrated circuit.

According to the invention this object is achieved by a test method with the features of claim 1 and a test device with the features of claim 9. According to these, provision is made for the following:

A test method for testing an integrated circuit according to a boundary scan description, having at least a boundary scan program, a hardware-related wiring plan of the integrated circuit and a test specimen, the integrated circuit having a memory and a number of terminal pins and being able to be controlled by means of a program-controlled control device, with the following steps:
loading the boundary scan program, which configures a simulation of a chain of boundary scan cells, into the memory by way of at least one predetermined terminal pin;
reading out and starting the execution of the stored boundary scan program;
applying the test specimen according to the boundary scan description for predetermined terminal pins, which correspond to the TAP interface and
evaluating the states resulting at the terminal pins after execution of the stored boundary scan program (claim 1).

A test device, in particular for operating the test method,
with a plurality of external terminals, by way of which the test specimen according to the boundary scan description is applied, an external terminal being connected respectively to just one terminal pin of the integrated circuit;
with the integrated circuit, having a memory, into which the boundary scan program is loaded, and a plurality of terminal pins and
with a program-controlled control device, which reads the boundary scan program from the memory, starts its execution and reads in the states resulting at the terminal pins (4) after execution of the stored boundary scan program and outputs the result to one or more terminal pins (4) (claim 9).

The idea underlying the present invention is essentially that of providing a test method and a test device for testing an integrated circuit according to a boundary scan description, with no need for any hardware provision for the boundary scan cells. In contrast, according to the invention, the boundary scan cells are simulated by the boundary scan program.

All the functionalities of the chain of boundary scan cells are provided by the use of the boundary scan program. The predetermined terminal pins similarly provide the functionalities of the known TAP interface.

The fact that there is no need for boundary scan cells in hardware form advantageously saves space within the test device. Such space-saving represents an immense cost-saving for manufacturers of integrated circuits.

The scope of the invention also includes a computer program, which, when run on a computer or computer network, executes the inventive method in one of its refinements.

The scope of the invention also includes a computer program with computer code means, to implement the inventive method in one of its refinements, when the program is executed on a computer or computer network. The program code means can in particular be stored on a computer-readable data medium.

The scope of the invention also includes a data medium, on which a data structure is stored, which, when loaded into a random-access and/or main memory of a computer or computer network, can execute the inventive method in one of its refinements.

The scope of the invention also includes a computer program product with program code means stored on a machine-readable medium, to implement the inventive method in one of its refinements, when the program is executed on a computer or computer network.

Computer program product here refers to the program as a marketable product. It can essentially be available in any form, for example on paper or a computer-readable data medium and can in particular be distributed by way of a data transmission network.

Advantageous refinements and developments of the invention will emerge from the subclaims and the description with reference to the drawing.

According to a preferred development the application of the test specimen according to the boundary scan description to predetermined terminal pins means that the loading of the test specimen according to the boundary scan description to [sic] predetermined terminal pins into the memory and the application of states defined by means of the stored test specimen to the terminal pins take place by means of the boundary scan program. Therefore states of the test specimen can not only be applied from outside by way of the external terminals and terminal pins but the test specimens can also be loaded into the memory and be applied to the terminal pins by means of the boundary scan program. Therefore two different options are advantageously provided for applying specific states of the test specimen.

According to a further preferred development the boundary scan description is configured according to the IEEE 1149.1 standard. The boundary scan description then has the features of a conventional BSDL (Boundary Scan Description Language) file as well as the inventive boundary scan program.

According to a further preferred development the boundary scan program is configured as a function of the hardware-related wiring plan of the respective integrated circuit and the boundary plan description.

According to a further preferred development the boundary scan cells defined according to the IEEE 1149.1 standard are simulated virtually by means of the boundary scan program.

Because there is no need for boundary scan cells in hardware form, savings are made on silicon surface and therefore also costs.

According to a preferred refinement the states at the terminal pins are evaluated by picking off an electric potential respectively at test points linked to a predetermined selection of terminal pins. The external terminals, to which there is direct access from outside, are advantageously used. It is advantageously not necessary for the inventive test method to pick off the electric potential respectively at all terminal pins.

According to a further preferred refinement, to evaluate the states at the terminal pins, the integrated circuit to be tested is coupled by way of its terminal pins to at least one further integrated circuit or a similar transparent component, such as a resistor or a coil for example, and the states at the terminal pins of the integrated circuit to be tested are then determined by way of a further integrated circuit connected to it or a similar transparent component. According to the invention the further integrated circuits can have no boundary scan cells or conventional boundary scan cells. Connecting a number of integrated circuits improves the test options.

According to a further preferred refinement the boundary scan program is loaded into the memory by way of a synchronous, asynchronous or bus interface—for example a CAN bus interface—of the integrated circuit.

The invention is described in more detail below with reference to exemplary embodiments set out in the schematic figures of the drawings, in which:

FIG. 1 shows a schematic block circuit diagram of a generally known test device for testing an integrated circuit;

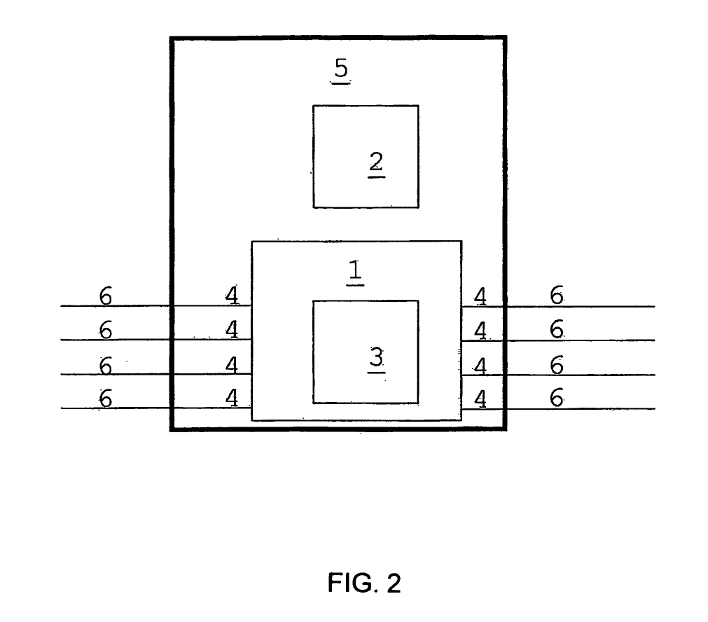

FIG. 2 shows a schematic block circuit diagram of a first exemplary embodiment of an inventive test device for testing an integrated circuit;

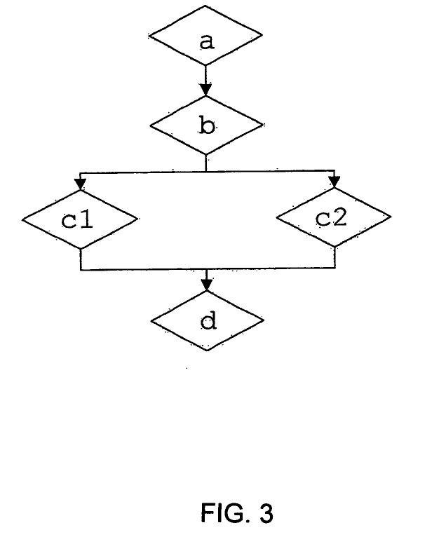

FIG. 3 shows a schematic flow diagram of a first exemplary embodiment of an inventive test method for testing an integrated circuit.

Elements that are the same or have the same function are shown with the same reference characters in all the figures of the drawings, unless otherwise specified.

FIG. 2 shows a schematic block circuit diagram of a first exemplary embodiment of an inventive test device for testing an integrated circuit. In the test device 5 an integrated circuit 1 is provided, having a memory 3 and a plurality of terminal pins 4. The test device 5 also has a program-controlled control device 2, which controls the integrated circuit 1.

The boundary scan program is loaded into the memory 3 by way of predetermined terminal pins 6. The boundary scan program configures a simulation of a chain of boundary scan cells. The program-controlled control device 2 reads the boundary scan program from the memory 3 and starts its execution. The test specimen according to the boundary scan description is applied to predetermined terminal pins 4 by way of a plurality of external terminals 6. The test specimen can thereby either be applied directly to predetermined terminal pins 4 or the test specimen is first loaded into the memory 3. States of the stored test specimen defined by means of the boundary scan program are then applied internally to other predetermined terminal pins 4. The program-controlled control device 2 evaluates the states resulting at the terminal pins 4 after execution of the stored boundary scan program. The states can be binary states for example.

FIG. 3 shows a schematic flow diagram of a first exemplary embodiment of an inventive test method for testing an integrated circuit. The test method for testing the integrated circuit is implemented according to a boundary scan description. The boundary scan description has at least a boundary scan program, a hardware-related wiring plan of the integrated circuit 1 and a test specimen, the integrated circuit 1 having a memory 3 and a plurality or terminal pins 4 and being able to be controlled by means of a program-controlled control device 2. The inventive test method has the following method steps:

Method Step a:

The boundary scan program, which configures a simulation of a chain of boundary scan cells, is loaded into the memory 3 by way of at least one predetermined terminal pin 4. The boundary scan program is preferably configured as a function of the hardware-related wiring plan of the integrated circuit 1 and the boundary scan description. The boundary scan cells defined according to the IEEE 1149.1 standard are advantageously simulated virtually by means of the boundary scan program. The boundary scan program is also preferably loaded into the memory 3 by way of a serial (SPI) interface or a CAN interface of the integrated circuit 1.

Method Step b:

The boundary scan program is read from the memory and its execution is started.

The subsequent method steps c1 and c2 represent two alternatives for applying the test specimen.

Method Step c1:

The test specimen is applied according to the boundary scan description directly by way of predetermined external terminals 6 to the terminal pins 4 coupled to said predetermined external terminals 6.

Method Step c2:

As an alternative to direct application of the test specimen to predetermined terminal pins 4, the application of the test specimen according to the boundary scan description to predetermined terminal pins 4 can also involve first of all loading the test specimen into the memory 3 and applying states defined by the stored test specimen to terminal pins 4 by means of the boundary scan program. The boundary scan description is preferably configured according to the IEEE 1149.1 standard.

Method Step d:

The states resulting at the terminal pins 4 after execution of the stored boundary scan program are evaluated. This evaluation makes it possible to detect whether and where connection errors (short circuits due to soldering jumpers or line breaks) exist within the wiring of the integrated circuit 1. The states at the terminal pins 4 are preferably evaluated by picking off an electric potential respectively at external terminals 6 coupled to a predetermined selection of terminal pins 4. Alternatively, to evaluate the states at the terminal pins 4, the integrated circuit 1 to be tested is coupled by way of its terminal pins 4 to at least one further integrated circuit. The states at the terminal pins 4 of the integrated circuit 1 to be tested are then determined by way of a further integrated circuit coupled to it. According to the invention the further integrated circuits can have no boundary scan cells or conventional boundary scan cells. Connecting a number of integrated circuits improves the test options for boundary scan testing, as the number of terminal pins 4 that can be accessed from outside increases.

Although the present invention was described above with reference to preferred exemplary embodiments, it is not limited to these but can be modified in many diverse ways. For example the interface, by way of which the boundary scan program is loaded, can be freely selected depending on the structure of the integrated circuit.

1-13. (canceled)

14. A test method for testing an integrated circuit according to a boundary scan description including at least a boundary scan program, a hardware-related wiring plan of the integrated circuit, and a testing scheme, the integrated circuit having a memory and a plurality of terminal pins and being capable of being controlled by a program-controlled control device, the method which comprises:
loading the boundary scan program into the memory by way of at least one predetermined terminal pin, and configuring with the boundary scan program a simulation of a chain of boundary scan cells;
reading out and starting an execution of the boundary scan program stored in the memory;
applying the testing scheme according to the boundary scan description to predetermined terminal pins; and
evaluating resulting states at the terminal pins after execution of the boundary scan program stored in the memory.

15. The test method according to claim 14, wherein the step of applying the testing scheme according to the boundary scan description to predetermined terminal pins includes: loading the testing scheme according to the boundary scan description into the memory by way of predetermined terminal pins and applying states defined by the stored testing scheme to the terminal pins by way of the boundary scan program.

16. The test method according to claim 14, which comprises configuring the boundary scan description according to the IEEE 1149.1 standard.

17. The test method according to claim 14, which comprises configuring the boundary scan program in dependence on the hardware-related wiring plan of the integrated circuit and the boundary scan description.

18. The test method according to claim 14, which comprises simulating boundary scan cells defined in the IEEE 1149.1 standard by way of the boundary scan program.

19. The test method according to claim 14, which comprises evaluating the states at the terminal pins by picking off an electric potential respectively at external terminals coupled to a predetermined selection of terminal pins.

20. The test method according to claim 14, which comprises, in order to evaluate the states at the terminal pins, coupling the terminal pins of the integrated circuit to be tested to at least one further integrated circuit or a similar transparent component and then determining the states at the terminal pins of the integrated circuit to be tested by way of the further integrated circuit or the similar transparent component.

21. The test method according to claim 14, which comprises loading the boundary scan into the memory by way of a synchronous, asynchronous, or CAN interface of the integrated circuit.

22. A test device configured to carry out the test method according to claim 14, the device comprising:
an integrated circuit having a plurality of terminal pins, said integrated circuit having a memory configured to load a boundary scan program therein;
a plurality of external terminals each connected to a respective single one of said plurality of terminal pins and configured to receive a testing scheme according to the boundary scan description;
a program-controlled control device configured to reads the boundary scan program from the memory, to start an execution of the boundary scan program, to read in resulting states at said terminal pins after execution of the boundary scan program stored in the memory, and to output a result to one or more of said terminal pins.

23. A test device for testing an integrated circuit according to a boundary scan description, the device comprising:
an integrated circuit having a plurality of terminal pins, said integrated circuit having a memory configured to load a boundary scan program therein;
a plurality of external terminals each connected to a respective single one of said plurality of terminal pins and configured to receive a testing scheme according to the boundary scan description;
a program-controlled control device configured to reads the boundary scan program from the memory, to start an execution of the boundary scan program, to read in resulting states at said terminal pins after execution of the boundary scan program stored in the memory, and to output a result to one or more of said terminal pins.

24. A computer program containing program code configured to execute the method according to claim 14, when the program is executed on a computer or a computer network.

25. The computer program according to claim 24, wherein the executable program code is stored on a computer-readable medium.

26. A data carrier having a data structure stored thereon, the data structure, when loaded into a random-access memory or a main memory of a computer or computer network, being capable of executing the method according to claim 14.

27. A computer program product with computer-executable program code stored on a machine-readable medium, the computer-executable program, upon being executed on a computer or computer network, implementing the steps according to claim 14.

28. A computer-readable medium having computer-executable instructions for performing the method according to claim 14 when executed on a computer or computer network.
